(19) United States
(12) Patent Application Publication
(10) Pub. No.: US 2009/0085664 A1
(43) Pub. Date: Apr. 2, 2009

(54) POWER AMPLIFIER HAVING AN ADAPTIVE AMPLIFYING MECHANISM

(76) Inventors: Po-Tang Yang, Pingtung City (TW); Rui-Ling Lai, Changhua County (TW)

Correspondence Address: NORTH AMERICA INTELLECTUAL PROPERTY CORPORATION, P.O. BOX 506, MERRIFIELD, VA, 22116, US

(21) Appl. No.: 11/864,916

(22) Filed: Sep. 29, 2007

(51) Int. Cl. H03F 3/16; H03F 1/22

(52) U.S. Cl. 330/277; 330/311

(57) ABSTRACT

By making use of two common-source amplifying units having a shared DC bias in conjunction with two current units or an extra amplifying unit, a power amplifier is capable of providing a high output power in a high power-gain operation and achieving a low power biasing consumption in a low power-gain operation. The two current units are utilized to provide auxiliary bias currents for diverting part of two bias currents corresponding to the shared DC bias for the two amplifying units so that the output power can be boosted in the high power-gain operation. Also, the extra amplifying unit can be coupled in series with the two amplifying units for improving the output power of the power amplifier in the high power-gain operation. The shared DC bias provides same bias current to the two amplifying units for achieving the low power biasing consumption in the low power-gain operation.

### BACKGROUND OF THE INVENTION

1. Field of the Invention

The present invention relates to a power amplifier, and more particularly, to a power amplifier having an adaptive amplifying mechanism.

2. Description of the Prior Art

In a radio communication system, a radio-frequency power amplifier is usually applied to amplify radio-frequency signals for transmission. In order to reduce power consumption for biasing, a cascode power amplifier with a shared DC bias, instead of a cascade power amplifier, has gained popularity in the design of the radio-frequency power amplifier. Please refer to FIG. 1, which is a circuit diagram schematically showing the structure of a prior art power amplifier 100 for amplifying radio-frequency signals.

The prior art power amplifier 100 is a cascode-based power amplifier and comprises a first amplifying unit 110, a second amplifying unit 120, a third amplifying unit 180, a switch unit 160, an impedance matching unit 170, inductors 131 and 132, and capacitors 101, 102 and 103.

The capacitors 101, 102 and 103 are utilized to couple AC signals and to block DC biases. The inductor 131 is utilized to couple a supply voltage Vdd to the second amplifying unit 120 for biasing. The inductor 132 is utilized to couple the supply voltage Vdd to the third amplifying unit 180 for biasing. The first amplifying unit 110 comprises a voltage source 111 for providing a bias voltage Vb1, a transistor 113 coupled to the capacitor 101 for receiving a radio-frequency input signal RFin, and a resistor 112 coupled between the voltage source 111 and the transistor 113. The resistor 112 is utilized to couple the corresponding DC bias and to block AC signals. The first amplifying unit 110 is operated as a common-source amplifier. The second amplifying unit 120 comprises a voltage source 121 for providing a bias voltage Vb2, a transistor 123 coupled to the transistor 113, and a resistor 122 coupled between the voltage source 121 and the transistor 123. The resistor 122 is utilized to couple the corresponding DC bias and to block AC signals. The second amplifying unit 120 is operated as a common-gate amplifier. The third amplifying unit 180 comprises a voltage source 181 for providing a bias voltage Vb3, a transistor 183 coupled to the transistor 123 via the capacitor 102, and a resistor 182 coupled between the voltage source 181 and the transistor 183. The resistor 182 is utilized to couple the corresponding DC bias and to block AC signals. The third amplifying unit 180 is operated as a common-source amplifier.

The switch unit 160 has a first input port coupled to the second amplifying unit 120, a second input port coupled to the third amplifying unit 180, a third input port coupled for receiving a control signal Sctrl, and an output port coupled to the impedance matching unit 170. The switch unit 160 couples the second amplifying unit 120 to the impedance matching unit 170 when the power amplifier 100 performs a low power-gain operation corresponding to the control signal Sctrl having a first-level value, and couples the third amplifying unit 180 to the impedance matching unit 170 when the power amplifier 100 performs a high power-gain operation corresponding to the control signal Sctrl having a second-level value. The impedance matching unit 170 is utilized to match the impedance concerning the second amplifying unit 120 or the third amplifying unit 180 for outputting an amplified radio-frequency signal RFout. Consequently, the impedance matching unit 170 is also controlled by the control signal Sctrl so as to provide proper impedance matching for the second amplifying unit 120 or the third amplifying unit 180.

Based on the above description, it is obvious that the second amplifying unit 120 functions as a current buffer, and the power gain of the power amplifier 100 is mainly due to the first amplifying unit 110 in the low power-gain operation. Furthermore, the switch unit 160, for transferring one of the amplified signals outputted from two amplifying units 120 and 180 to the impedance matching unit 170, will decay the power of the amplified signal being transferred owing to the switching components of the switch unit 160. Still more, the impedance matching unit 170 is required to provide impedance matching having two different matching values in response to the control signal Sctrl, which results in a complicated circuit design for the impedance matching unit 170.

### SUMMARY OF THE INVENTION

The present invention provides a power amplifier comprising a first transistor, a first bias unit, a first resistor, a second transistor, a second bias unit, a second resistor, a first capacitor, a first inductor and a second capacitor. The first transistor has a gate coupled to an input port of the power amplifier for receiving an input signal, a first terminal coupled to a ground terminal, and a second terminal. The first bias unit is coupled to the gate of the first transistor. The first resistor is coupled between the first bias unit and the gate of the first transistor. The second transistor has a gate coupled to the second terminal of the first transistor, a first terminal coupled to the second terminal of the first transistor, and a second terminal coupled to an output port of the power amplifier for outputting an output signal. The second bias unit is coupled to the gate of the second transistor. The second resistor is coupled between the second bias unit and the gate of the second transistor. The first capacitor is coupled between the first terminal of the second transistor and the ground terminal. The first inductor is coupled between the first terminal of the second transistor and the second terminal of the first transistor. The second capacitor is coupled between the gate of the second transistor and the second terminal of the first transistor.

The present invention further provides a power amplifier comprising a first transistor, a first bias unit, a first resistor, a second transistor, a second bias unit, a second resistor, a first capacitor, a third resistor, a second capacitor, a first current unit and a second current unit. The first transistor has a gate coupled to an input port of the power amplifier for receiving an input signal, a first terminal coupled to a ground terminal, and a second terminal. The first bias unit is coupled to the gate of the first transistor. The first resistor is coupled between the first bias unit and the gate of the first transistor. The second transistor has a gate coupled to the second terminal of the first transistor, a first terminal coupled to the second terminal of the first transistor, and a second terminal coupled to an output port of the power amplifier for outputting an output signal. The second bias unit is coupled to the gate of the second transistor. The second resistor is coupled between the second bias unit and the gate of the second transistor. The first capacitor is coupled between the first terminal of the second transistor and the ground terminal. The third resistor is coupled between the first terminal of the second transistor and the second terminal of the first transistor. The second capacitor is coupled between the gate of the second transistor and the second terminal of the first transistor. The first current unit is coupled to the second terminal of the first transistor. The second current unit is coupled to the first terminal of the second transistor.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a circuit diagram schematically showing the structure of a prior art power amplifier.

FIG. 2 is a block diagram schematically showing the structure of a power amplifier according to the present invention.

FIG. 3 is a circuit diagram schematically showing the structure of a power amplifier in accordance with a first preferred embodiment of the present invention.

FIG. 4 is a circuit diagram schematically showing the structure of a power amplifier in accordance with a second preferred embodiment of the present invention.

### DETAILED DESCRIPTION

Hereinafter, preferred embodiments of the present invention will be described in detail with reference to the accompanying drawings. Here, it is to be noted that the present invention is not limited thereto.

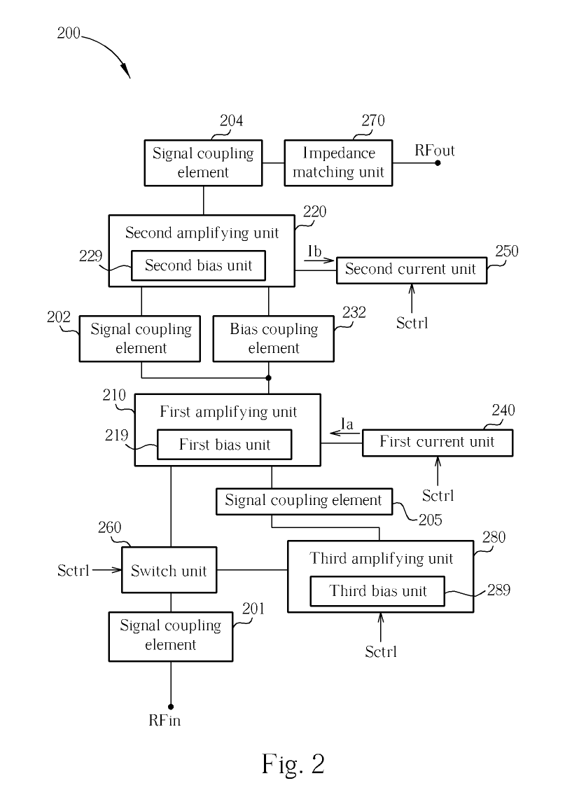

Please refer to FIG. 2, which is a block diagram schematically showing the structure of a power amplifier 200 according to the present invention. The power amplifier 200 comprises a first amplifying unit 210, a second amplifying unit 220, a third amplifying unit 280, a switch unit 260, a first current unit 240, a second current unit 250, an impedance matching unit 270, a bias coupling element 232, and signal coupling elements 201, 202, 204 and 205.

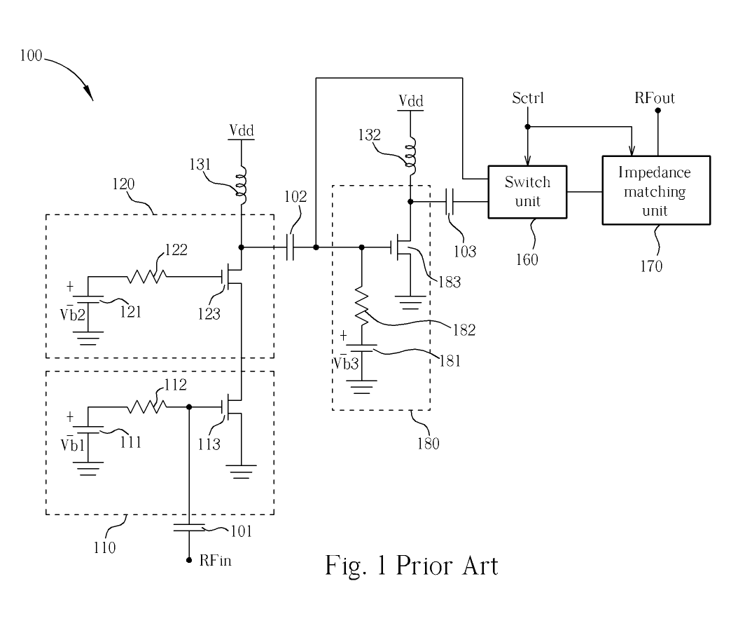

The signal coupling elements 201, 202, 204 and 205 are utilized to couple AC signals and to block DC biases. On the contrary, the bias coupling element 232 is utilize to couple a DC bias and to block an AC signal. That is, the first amplifying unit 210 and the second amplifying unit 220 share the same DC bias through the bias coupling element 232 so as to reduce the power consumption of the DC bias for the first and second amplifying units 210, 220. The first through third power amplifiers 210, 220 and 280 comprise a first bias unit 219, a second bias unit 229 and a third bias unit 289 respectively for providing DC biases. The impedance matching unit 270 is utilized only to provide the impedance matching for the second amplifying unit 220 so as to output an output signal Rfout efficiently. Accordingly, the circuit of the impedance matching unit 270 is not required to be so complicated as that of the impedance matching unit 170 shown in FIG. 1, and the power of the output signal RFout is delivered more efficiently.

The switch unit 260 has a first input port coupled to the signal coupling element 201 for receiving an input signal RFin, a second input port coupled for receiving a control signal Sctrl, a first output port coupled to the first amplifying unit 210, and a second output port coupled to the third amplifying unit 280. The switch unit 260 can be an electronic relay or a multiplexer. The switch unit 260 transfers the input signal RFin to the first amplifying unit 210 or the third amplifying unit 280 in response to the control signal Sctrl. Besides, whether the third amplifying unit 280 is active or not is also controlled by the control signal Sctrl.

For instance, when the control signal Sctrl is a first-level signal corresponding to a low power-gain operation of the power amplifier 200, the switch unit 260 transfers the input signal RFin to the first amplifying unit 210 and the third amplifying unit 280 is inactive, which means that the input signal RFin is amplified only by the first and second amplifying units 210 and 220. When the control signal Sctrl is a second-level signal corresponding to a high power-gain operation of the power amplifier 200, the third amplifying unit 280 is active and the switch unit 260 transfers the input signal RFin to the third amplifying unit 280, which means that the input signal RFin is amplified by the first through third amplifying units 210, 220 and 280.

Furthermore, whether the first and second current units 240, 250 are active or not is controlled by the control signal Sctrl as well. The first current unit 240 can be a controllable current source having a first terminal coupled for receiving a supply voltage, a second terminal coupled to the first amplifying unit 210, and a third terminal coupled for receiving the control signal Sctrl. The second current unit 250 can be another controllable current source having a first terminal coupled to a ground terminal, a second terminal coupled to the second amplifying unit 220, and a third terminal coupled for receiving the control signal Sctrl.

When the control signal Sctrl is a second-level signal corresponding to the high power-gain operation of the power amplifier 200, the first current unit 240 is active and functions to provide an auxiliary bias current Ia to the first amplifying unit 210, and the second current unit 250 is also active and functions to sink an auxiliary bias current Ib from the second amplifying unit 220. Accordingly, with the aid of the auxiliary bias currents Ia and Ib, the current flowing through the bias coupling element 232 can be reduced. Under such situation, when the bias coupling element 232 is a resistor, lower current flowing through the bias coupling element 232 in turn reduces the voltage drop across the bias coupling element 232 so that the power gain of the first amplifying unit 210 can be boosted for achieving the high power-gain operation.

That is, when the control signal Sctrl is a first-level signal, the third amplifying unit 280, the first current unit 240 and the second current unit 250 are all inactive, and the input signal RFin is amplified only by the first and second amplifying units 210, 220 without the aid of the auxiliary currents Ia and Ib, which corresponds to the low power-gain operation of the power amplifier 200 having feature of providing the shared DC bias for achieving a low power biasing consumption. When the control signal Sctrl is a second-level signal, the third amplifying unit 280, the first current unit 240 and the second current unit 250 are all active, and the input signal RFin is amplified by the first through third amplifying units 210, 220 and 280 with the aid of the auxiliary currents Ia and Ib, which corresponds to the high power-gain operation of the power amplifier 200 having feature of providing a high power gain.

Based on the above description, it is quite obvious that the power gain of the power amplifier 200 can be boosted with the aid of the third amplifying unit 280 or the first and second current units 240 and 250. From another point of view, when the power gain is not so highly demanded, the power amplifier 200 can be implemented with either the third amplifying unit 280 or the first and second current units 240 and 250, which means that either the third amplifying unit 280 or the first and second current units 240 and 250 can be omitted.

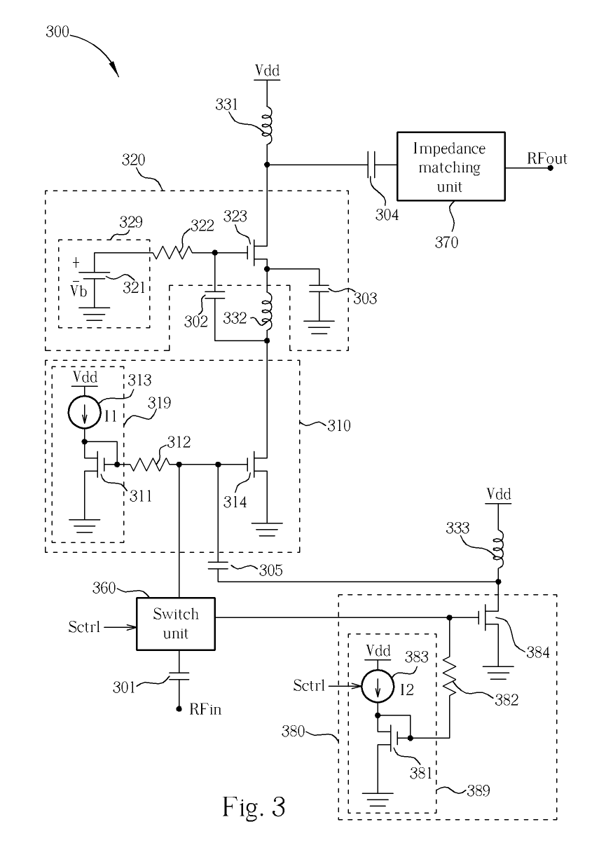

Please refer to FIG. 3, which is a circuit diagram schematically showing the structure of a power amplifier 300 in accordance with a first preferred embodiment of the present invention. The power amplifier 300 comprises a first amplifying unit 310, a second amplifying unit 320, a third amplifying unit 380, a switch unit 360, an impedance matching unit 370, inductors 331, 332 and 333, and capacitors 301, 302, 304 and 305.

The capacitors 301, 302, 304 and 305 are utilized to couple AC signals and to block DC biases. The inductor 332 is utilize to couple a DC bias and to block an AC signal, which means that the first amplifying unit 310 and the second amplifying unit 320 share the same DC bias through the inductor 332 so as to reduce the power consumption of the DC bias for the first and second amplifying units 310, 320. The inductor 331 is utilized to couple a supply voltage Vdd to the second amplifying unit 320 for biasing. The inductor 333 is utilized to couple the supply voltage Vdd to the third amplifying unit 380 for biasing. The impedance matching unit 370 is utilized only to provide the impedance matching for the second amplifying unit 320 so as to output an output signal Rfout efficiently. Accordingly, the circuit of the impedance matching unit 370 is also not required to be as complicated as that of the impedance matching unit 170 shown in FIG. 1, and the power of the output signal RFout can be delivered more efficiently.

The switch unit 360 has a first input port coupled for receiving an input signal RFin via the capacitor 301, a second input port coupled for receiving a control signal Sctrl, a first output port coupled to the first amplifying unit 310, and a second output port coupled to the third amplifying unit 380. The switch unit 360 can be an electronic relay or a multiplexer. The switch unit 360 transfers the input signal RFin to the first amplifying unit 310 or the third amplifying unit 380 in response to the control signal Sctrl. Besides, whether the third amplifying unit 380 is active or not is also controlled by the control signal Sctrl. For instance, when the control signal Sctrl is a first-level signal corresponding to the low power-gain operation of the power amplifier 300, the switch unit 360 transfers the input signal RFin to the first amplifying unit 310 and the third amplifying unit 380 is inactive. When the control signal Sctrl is a second-level signal corresponding to the high power-gain operation of the power amplifier 300, the third amplifying unit 380 is active and the switch unit 360 transfers the input signal RFin to the third amplifying unit 380.

The first amplifying unit 310 is operated as a common-source amplifier and comprises a first bias unit 319, a resistor 312 and a transistor 314. The first bias unit 319 comprises a transistor 311 and a current source 313. The transistor 311 is an NMOS transistor and has a first terminal coupled to a ground terminal, a second terminal coupled to the current source 313, and a gate coupled to the second terminal. The current source 313 is coupled to receive the supply voltage Vdd for providing a bias reference current I1. The transistor 314 is an NMOS transistor and has a first terminal coupled to the ground terminal, a second terminal coupled to the second amplifying unit 320 through the capacitor 302 and the inductor 332, and a gate coupled to the first output port of the switch unit 360. The resistor 312 is coupled between the gate of the transistor 311 and the gate of the transistor 314.

The second amplifying unit 320 comprises a second bias unit 329, a resistor 322, a capacitor 303 and a transistor 323. The second bias unit 329 comprises a voltage source 321 for providing a bias voltage Vb. The transistor 323 is an NMOS transistor and has a first terminal coupled to the inductor 332 and the capacitor 303, a second terminal coupled for receiving the supply voltage Vdd via the inductor 331, and a gate coupled to the capacitor 302. The second terminal of the transistor 323 is also coupled to the impedance matching unit 370 via the capacitor 304. The resistor 322 is coupled between the gate of the transistor 323 and the voltage source 321. The capacitor 303 is coupled between the first terminal of the transistor 323 and the ground terminal so that the second amplifying unit 320 can be also operated as a common-source amplifier.

The third amplifying unit 380 comprises a third bias unit 389, a resistor 382 and a transistor 384. The third bias unit 389 comprises a transistor 381 and a current source 383. The transistor 381 is an NMOS transistor and has a first terminal coupled to a ground terminal, a second terminal coupled to the current source 383, and a gate coupled to the second terminal. The current source 383 is coupled to receive the supply voltage Vdd for providing a bias reference current I2. Please note that the current source 383 is controlled by the control signal Sctrl, and the third amplifying unit 380 is inactive when the current source 383 is turned off by the control signal Sctrl. The transistor 384 is an NMOS transistor and has a first terminal coupled to the ground terminal, a second terminal coupled to the gate of the transistor 314 through the capacitor 305, and a gate coupled to the second output port of the switch unit 360. The second terminal of the transistor 384 is also coupled for receiving the supply voltage Vdd via the inductor 333. The resistor 382 is coupled between the gate of the transistor 381 and the gate of the transistor 384.

Accordingly, when the control signal Sctrl is a first-level signal, the third amplifying unit 380 is inactive, and the input signal RFin is amplified only by the first and second amplifying units 310, 320, which corresponds to the low power-gain operation of the power amplifier 300 having feature of providing the shared DC bias for achieving a low power biasing consumption. When the control signal Sctrl is a second-level signal, the third amplifying unit 380 is active, and the input signal RFin is amplified by the first through third amplifying units 310, 320 and 380, which corresponds to the high power-gain operation of the power amplifier 300 having feature of providing a high power gain.

It is well known that a large device area is required to devise an inductor, which may be an inductor simulator based on electronic circuits or a micro-machined solenoid inductor based on photolithography technique. Therefore, the inductor 332 can be replaced with a coupling resistor in order to save chip area. However, the voltage drop across the coupling resistor will reduce the power gain of the first amplifying unit 310. Please note that the inductors 331 and 333 can be placed outside the chip designed for the main circuits of the power amplifier 300.

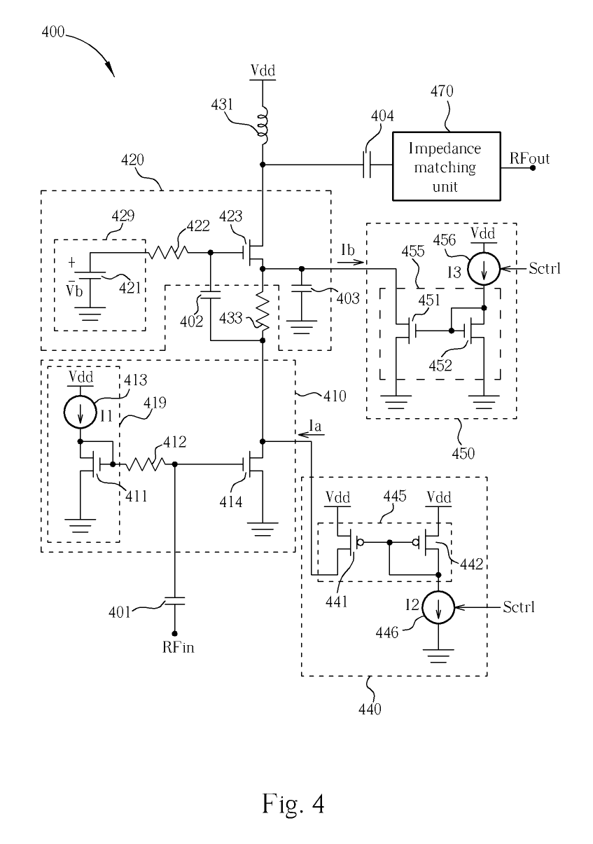

Please refer to FIG. 4, which is a circuit diagram schematically showing the structure of a power amplifier 400 in accordance with a second preferred embodiment of the present invention. The power amplifier 400 comprises a first amplifying unit 410, a second amplifying unit 420, a first current unit 440, a second current unit 450, an impedance matching unit 470, an inductor 431, a resistor 433,and capacitors 401, 402 and 404.

The capacitors 401, 402 and 404 are utilized to couple AC signals and to block DC biases. The first amplifying unit 410 and the second amplifying unit 420 share the same DC bias through the resistor 433 so as to reduce the power consumption of the DC bias for the first and second amplifying units 410, 420. The inductor 431, which can be placed outside the chip designed for the main circuits of the power amplifier 400, is utilized for coupling the supply voltage Vdd to the second amplifying unit 420 for biasing. The impedance matching unit 470 is utilized only to provide the impedance matching for the second amplifying unit 420 so as to output an output signal RFout efficiently. Accordingly, the circuit of the impedance matching unit 470 is also not required to be as complicated as that of the impedance matching unit 170 shown in FIG. 1, and the power of the output signal RFout can be delivered more efficiently.

The first amplifying unit 410 is operated as a common-source amplifier and comprises a first bias unit 419, a resistor 412 and a transistor 414. The first bias unit 419 comprises a transistor 411 and a current source 413. The transistor 411 is an NMOS transistor and has a first terminal coupled to a ground terminal, a second terminal coupled to the current source 413, and a gate coupled to the second terminal. The current source 413 is coupled to receive the supply voltage Vdd for providing a bias reference current I1. The transistor 414 is an NMOS transistor and has a first terminal coupled to the ground terminal, a second terminal coupled to the second amplifying unit 420 through the capacitor 402 and the resistor 433, and a gate coupled for receiving an input signal RFin through the capacitor 401. The resistor 412 is coupled between the gate of the transistor 411 and the gate of the transistor 414.

The second amplifying unit 420 comprises a second bias unit 429, a resistor 422, a capacitor 403 and a transistor 423. The second bias unit 429 comprises a voltage source 421 for providing a bias voltage Vb. The transistor 423 is an NMOS transistor and has a first terminal coupled to the resistor 433 and the capacitor 403, a second terminal coupled for receiving the supply voltage Vdd via the inductor 431, and a gate coupled to the capacitor 402. The second terminal of the transistor 423 is also coupled to the impedance matching unit 470 via the capacitor 404. The resistor 422 is coupled between the gate of the transistor 423 and the voltage source 421. The capacitor 403 is coupled between the first terminal of the transistor 423 and the ground terminal so that the second amplifying unit 420 can be also operated as a common-source amplifier.

Because of the voltage drop across the resistor 433, the power gain of the first amplifying unit 410 is decreased, and the situation becomes worse in the high power-gain operation of the power amplifier 400. Accordingly, the first current unit 440 and the second current unit 450 are introduced for reducing the voltage drop across the resistor 433 in the high power-gain operation of the power amplifier 400. The first and second current units 440, 450 are controlled by the control signal Sctrl. When the control signal Sctrl is a second-level signal corresponding to the high power-gain operation of the power amplifier 400, the first current unit 440 is active and functions to provide an auxiliary bias current Ia to the first amplifying unit 410, and the second current unit 450 is also active and functions to sink an auxiliary bias current Ib from the second amplifying unit 420. Accordingly, with the aid of the auxiliary bias currents Ia and Ib, the current flowing through the resistor 433 can be reduced, which in turn reduces the voltage drop across the resistor 433 so that the power gain of the first amplifying unit 410 can be boosted for achieving the high power-gain operation.

The first current unit 440 comprises a current source 446 and a current mirror 445. The current mirror 445 comprises two transistors 441 and 442. The current source 446 is coupled to the ground terminal for providing a sinking current I2. Please note that the current source 446 is controlled by the control signal Sctrl, and the first current unit 440 is inactive when the current source 446 is turned off by the control signal Sctrl. The transistor 442 is a PMOS transistor and has a first terminal coupled for receiving the supply voltage Vdd, a second terminal coupled to the current source 446, and a gate coupled to the second terminal. The transistor 441 is a PMOS transistor and has a first terminal coupled for receiving the supply voltage Vdd, a gate coupled to the gate of the transistor 442, and a second terminal coupled to the second terminal of the transistor 414 for providing the auxiliary bias current Ia to the first amplifying unit 410.

The second current unit 450 comprises a current source 456 and a current mirror 455. The current mirror 455 comprises two transistors 451 and 452. The current source 456 is coupled to receive the supply voltage Vdd for providing a current I3. Please note that the current source 456 is controlled by the control signal Sctrl, and the second current unit 450 is inactive when the current source 456 is turned off by the control signal Sctrl. The transistor 452 is a NMOS transistor and has a first terminal coupled to the ground terminal, a second terminal coupled to the current source 456, and a gate coupled to the second terminal. The transistor 451 is a NMOS transistor and has a first terminal coupled to the ground terminal, a gate coupled to the gate of the transistor 452, and a second terminal coupled to the first terminal of the transistor 423 for sinking the auxiliary bias current Ib from the second amplifying unit 420.

Accordingly, when the control signal Sctrl is a first-level signal, both the first and second current units 440, 450 are inactive, and the input signal RFin is amplified by the first and second amplifying units 410, 420 without the aid of the auxiliary currents Ia and Ib, which corresponds to the low power-gain operation of the power amplifier 400 having feature of providing the shared DC bias for achieving a low power biasing consumption. When the control signal Sctrl is a second-level signal, both the first and second current units 440, 450 are active, and the input signal RFin is amplified by the first and second amplifying units 410, 420 with the aid of the auxiliary currents Ia and Ib, which corresponds to the high power-gain operation of the power amplifier 400 having feature of providing a high power gain.

In summary, by making use of two common-source amplifying units having a shared DC bias in conjunction with two current units or an extra amplifying unit, the power amplifier circuit of the present invention is capable of providing a high output power for the high power-gain operation and achieving a low power biasing consumption for the low power-gain operation. The two current units are utilized to provide auxiliary bias currents for diverting part of the two bias currents corresponding to the shared DC bias for the two amplifying units so that the output power of the power amplifier can be boosted in the high power-gain operation. Also, the extra amplifying unit can be coupled in series with the two amplifying units for improving the output power of the power amplifier in the high power-gain operation. The two current units and the extra amplifying unit are inactive in the low power-gain operation, and the shared DC bias provides same bias current to the two amplifying units for achieving the low power biasing consumption.

Those skilled in the art will readily observe that numerous modifications and alterations of the device and method may be made while retaining the teachings of the invention.

What is claimed is:

1. A power amplifier comprising:
a first transistor having a gate coupled to an input port of the power amplifier for receiving an input signal, a first terminal coupled to a ground terminal, and a second terminal;
a first bias unit coupled to the gate of the first transistor;
a first resistor coupled between the first bias unit and the gate of the first transistor;
a second transistor having a gate coupled to the second terminal of the first transistor, a first terminal coupled to the second terminal of the first transistor, and a second terminal coupled to an output port of the power amplifier for outputting an output signal;
a second bias unit coupled to the gate of the second transistor;
a second resistor coupled between the second bias unit and the gate of the second transistor;
a first capacitor coupled between the first terminal of the second transistor and the ground terminal;
a first inductor coupled between the first terminal of the second transistor and the second terminal of the first transistor; and
a second capacitor coupled between the gate of the second transistor and the second terminal of the first transistor.

2. The power amplifier of claim 1, further comprising:
a third capacitor coupled between the gate of the first transistor and the input port of the power amplifier; and
a fourth capacitor coupled between the second terminal of the second transistor and the output port of the power amplifier.

3. The power amplifier of claim 2, wherein the first through third capacitors are MOS capacitors or MIM (metal-insulator-metal) capacitors; and the first and second transistors are NMOS transistors.

4. The power amplifier of claim 1, further comprising:
an impedance matching unit coupled between the second terminal of the second transistor and the output port of the power amplifier.

5. The power amplifier of claim 1, further comprising:
a switch unit having a first input port coupled to the input port of the power amplifier, a second input port coupled for receiving a control signal, a first output port coupled to the gate of the first transistor, and a second output port; and
an amplifying unit having an input port coupled to the second output port of the switch unit and an output port coupled to the gate of the first transistor;
wherein the switch unit is an electronic relay or a multiplexer.

6. The power amplifier of claim 5, further comprising:
a third capacitor coupled between the output port of the amplifying unit and the gate of the first transistor; and
a second inductor having a first terminal coupled to the output port of the amplifying unit and a second terminal coupled for receiving a supply voltage.

7. The power amplifier of claim 5, wherein the amplifying unit comprises:
a third transistor having a gate coupled to the input port of the amplifying unit, a first terminal coupled to the ground terminal, and a second terminal coupled to the output port of the amplifying unit;
a third bias unit coupled to the gate of the third transistor; and
a third resistor coupled between the third bias unit and the gate of the third transistor.

8. The power amplifier of claim 7, wherein the third bias unit comprises:
a fourth transistor having a gate coupled to the third resistor, a first terminal coupled to the ground terminal, and a second terminal coupled to the gate of the fourth transistor; and
a current source having a first terminal coupled for receiving a supply voltage, a second terminal coupled to the second terminal of the fourth transistor, and a third terminal coupled for receiving the control signal.

9. The power amplifier of claim 8, wherein the third and fourth transistors are NMOS transistors.

10. The power amplifier of claim 1, wherein the first bias unit comprises:
a third transistor having a gate coupled to the first resistor, a first terminal coupled to the ground terminal, and a second terminal coupled to the gate of the third transistor; and
a current source having a first terminal coupled for receiving a supply voltage and a second terminal coupled to the second terminal of the third transistor;
wherein the third transistor is an NMOS transistor.

11. The power amplifier of claim 1, wherein the second bias unit comprises:
a voltage source having a first terminal coupled to the second resistor and a second terminal coupled to the ground terminal.

12. The power amplifier of claim 1, further comprising:
a second inductor having a first terminal coupled to the second terminal of the second transistor and a second terminal coupled for receiving a supply voltage.

13. A power amplifier comprising:
a first transistor having a gate coupled to an input port of the power amplifier for receiving an input signal, a first terminal coupled to a ground terminal, and a second terminal;
a first bias unit coupled to the gate of the first transistor;
a first resistor coupled between the first bias unit and the gate of the first transistor;
a second transistor having a gate coupled to the second terminal of the first transistor, a first terminal coupled to the second terminal of the first transistor, and a second terminal coupled to an output port of the power amplifier for outputting an output signal;
a second bias unit coupled to the gate of the second transistor;
a second resistor coupled between the second bias unit and the gate of the second transistor;
a first capacitor coupled between the first terminal of the second transistor and the ground terminal;
a third resistor coupled between the first terminal of the second transistor and the second terminal of the first transistor;
a second capacitor coupled between the gate of the second transistor and the second terminal of the first transistor;
a first current unit coupled to the second terminal of the first transistor; and
a second current unit coupled to the first terminal of the second transistor.

14. The power amplifier of claim 13, further comprising:
a third capacitor coupled between the gate of the first transistor and the input port of the power amplifier; and
a fourth capacitor coupled between the second terminal of the second transistor and the output port of the power amplifier.

15. The power amplifier of claim 14, wherein the first through third capacitors are MOS capacitors or MIM (metal-insulator-metal) capacitors; and the first and second transistors are NMOS transistors.

16. The power amplifier of claim 13, further comprising:
an impedance matching unit coupled between the second terminal of the second transistor and the output port of the power amplifier.

17. The power amplifier of claim 13, wherein the first bias unit comprises:
a third transistor having a gate coupled to the first resistor, a first terminal coupled to the ground terminal, and a second terminal coupled to the gate of the third transistor; and
a current source having a first terminal coupled for receiving a supply voltage and a second terminal coupled to the second terminal of the third transistor;
wherein the third transistor is an NMOS transistor.

18. The power amplifier of claim 13, wherein the second bias unit comprises:
a voltage source having a first terminal coupled to the second resistor, and a second terminal coupled to the ground terminal.

19. The power amplifier of claim 13, further comprising:
a second inductor having a first terminal coupled to the second terminal of the second transistor, and a second terminal coupled for receiving a supply voltage.

20. The power amplifier of claim 13, wherein the first current unit comprises:
a current source having a first terminal coupled to the ground terminal, a second terminal, and a third terminal coupled for receiving a control signal; and
a current mirror coupled between the second terminal of the current source and the second terminal of the first transistor.

21. The power amplifier of claim 20, wherein the current mirror comprises:
a third transistor having a first terminal coupled for receiving a supply voltage, a second terminal coupled to the second terminal of the current source, and a gate coupled to the second terminal of the third transistor; and
a fourth transistor having a first terminal coupled for receiving the supply voltage, a second terminal coupled to the second terminal of the first transistor, and a gate coupled to the gate of the third transistor;
wherein the third and fourth transistors are PMOS transistors.

22. The power amplifier of claim 13, wherein the second current unit comprises:
a current source having a first terminal coupled for receiving a supply voltage, a second terminal, and a third terminal coupled for receiving a control signal; and
a current mirror coupled between the second terminal of the current source and the first terminal of the second transistor.

23. The power amplifier of claim 22, wherein the current mirror comprises:
a third transistor having a first terminal coupled to the ground terminal, a second terminal coupled to the second terminal of the current source, and a gate coupled to the second terminal of the third transistor; and
a fourth transistor having a first terminal coupled to the ground terminal, a second terminal coupled to the first terminal of the second transistor, and a gate coupled to the gate of the third transistor;
wherein the third and fourth transistors are NMOS transistors.

24. The power amplifier of claim 13, wherein the first current unit comprises:
a controllable current source having a first terminal coupled for receiving a supply voltage, a second terminal coupled to the second terminal of the first transistor, and a third terminal coupled for receiving a control signal.

25. The power amplifier of claim 13, wherein the second current unit comprises:
a controllable current source having a first terminal coupled to the ground terminal, a second terminal coupled to the first terminal of the second transistor, and a third terminal coupled for receiving a control signal.
